(19) United States
(12) Patent Application Publication
(10) Pub. No.: US 2009/0266399 A1
(43) Pub. Date: Oct. 29, 2009

(54) METALLIC FOIL SUBSTRATE AND PACKAGING TECHNIQUE FOR THIN FILM SOLAR CELLS AND MODULES

(76) Inventors: Bulent M. Basol, Manhattan Beach, CA (US); Mustafa Pinarbasi, Morgan Hill, CA (US)

Correspondence Address: PILLSBURY WINTHROP SHAW PITTMAN LLP, P.O. BOX 10500, MCLEAN, VA, 22102, US

(21) Appl. No.: 12/163,162

(22) Filed: Jun. 27, 2008

Related U.S. Application Data
(63) Continuation-in-part of application No. 12/111,161, filed on Apr. 28, 2008.

(51) Int. Cl. H01L 31/042; H01L 31/00; B29C 65/72

(52) U.S. Cl. 136/244; 136/256; 156/220

(57) ABSTRACT

Methods of forming thin film solar cells with a metallic substrate are described, as well as solar cells and solar cells strings. The front surface of the metallic substrate is polished to form a polished front surface so that the average roughness of the polished front surface is less than 50 nm. The back surface of the metallic substrate is roughened to form a rough back surface so that the average roughness of the conditioned back surface is more than 500 nm. A Group IBIIIAVIA compound absorber layer is formed over the polished front surface.

### RELATED APPLICATION

The above referenced application is a continuation in part of U.S. patent application Ser. No. 12/111,161, filed Apr. 28, 2008, to which this application claims priority and the contents of which are expressly incorporated by reference herein.

### BACKGROUND

1. Field of the Invention

The present invention generally relates to thin film solar cell fabrication and module packaging, more particularly, to techniques for manufacturing modules based on Group IBIIIAVIA thin film solar cells.

2. Description of the Related Art

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ(S_{y}Se_{1-y})ₖ, where 0≦x≦1, 0≦y≦1 and k is approximately 2, have already been employed in solar cell structures that yielded conversion efficiencies approaching 20%. It should be noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The structure of a conventional Group IBIIIAVIA compound photovoltaic cell such as a Cu(In,Ga,Al)(S,Se,Te)₂ thin film solar cell is shown in FIG. 1. A photovoltaic cell 10 is fabricated on a substrate 11, such as a sheet of glass, a sheet of metal, an insulating foil or web, or a conductive foil or web. An absorber film 12, which comprises a material in the family of Cu(In,Ga,Al)(S,Se,Te)₂, is grown over a conductive layer 13 or contact layer, which is previously deposited on the substrate 11 and which acts as the electrical contact to the device. The substrate 11 and the conductive layer 13 form a base 20 on which the absorber film 12 is formed. Various conductive layers comprising Mo, Ta, W, Ti, and their nitrides have been used in the solar cell structure of FIG. 1. If the substrate itself is a properly selected conductive material, it is possible not to use the conductive layer 13, since the substrate 11 may then be used as the ohmic contact to the device. After the absorber film 12 is grown, a transparent layer 14 such as a CdS, ZnO, CdS/ZnO or CdS/ZnO/ITO stack is formed on the absorber film 12. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side.

If the substrate 11 of the CIGS(S) type cell shown in FIG. 1 is a metallic foil, then under illumination, a positive voltage develops on the substrate 11 with respect to the transparent layer 14. In other words, an electrical wire (not shown) that may be attached to the substrate 11 would constitute the (+) terminal of the solar cell 10 and a lead (not shown) that may be connected to the transparent layer 14 (or to a busbar of a metallic grid that may be deposited on the transparent layer 14) would constitute the (−) terminal of the solar cell.

After fabrication, individual solar cells are typically assembled into solar cell strings and circuits by interconnecting them (usually in series) electrically, i.e. by connecting the (+) terminal of one cell to the (−) terminal of a neighboring cell. This way the total voltage of the solar cell circuit is increased. The solar cell circuit is then laminated into a protective package to form a photovoltaic module.

For a device structure of FIG. 1, if the substrate 11 is a conductive metallic foil, series interconnection of cells may be carried out by connecting the substrate 11 at the back or un-illuminated side of one particular cell to the busbar of a finger pattern (not shown) at the front or illuminated side of the adjacent cell. A common industry practice is to use conductive wires, preferably in the form of strips of flat conductors or ribbons to interconnect a plurality of solar cells to form first a circuit and then a module as described before. Such ribbons are typically made of copper coated with tin and/or silver. For standard crystalline Si-based technology ribbons arc attached to the front and back sides of the cells in the module structure using a suitable soldering material since both the top contact of the cell, i.e. the busbar of the finger pattern, and the bottom contact of the cell comprise easily solderable metallic materials such as Ag. High temperature solders with processing temperatures in excess of 200° C., typically in excess of 300° C., may be used in the interconnection of Si cells to form “strings” which may then be interconnected by a process called “bussing” to form the module circuit.

Unlike Si solar cells, the thin film Group IBIIIAVIA compound solar cell of FIG. 1 may be fabricated on a metallic foil substrate such as a flexible stainless steel web or aluminum alloy foil. These materials may not be easily soldered, especially since the process temperature for this type of solar cell is limited to less than about 250° C., preferably less than 200° C. Therefore, conductive adhesives are usually employed to attach the Cu ribbons to the front contact or busbar and the back contact or the back surface of the substrate of such solar cells during their interconnection. Although such techniques are in use in products, contact resistance of the electrical contacts attached by conductive adhesives to metal foil based thin film solar cells still needs to be reduced. Adhesion of the contact to the back surface of the metallic foil substrates also needs improvement.

Module packaging methods used for Si solar cells do not necessarily yield good results in packaging thin film cells fabricated on prior art metallic foil substrates. Reliability of modules are usually tested through standard accelerated lifetime measurements that involve exposing the package to 85° C. temperature at 85% relative humidity, cycling the module temperature between 85° C. and −40° C., and repeating the temperature cycling steps in a humidity chamber (humidity freeze test). One problem observed in such tests is the loss of adhesion between the metallic foil substrates and the polymeric materials such as ethyl vinyl acetate (EVA) or thermo-plastic materials that are used in the module structure. Especially stresses induced during temperature cycling at the “back contact/metal substrate” interface and the “polymeric packaging material/metal substrate” interface cause adhesion failures and negatively impact the expected 25-year reliability of such modules.

In a typical solar cell string or circuit formation process flow the solar cells are first completely formed except the top contact and the bottom contact. The cells are then measured under standard illumination and separated or binned according to their efficiency or short circuit current values. This process is often called “cell sorting”. Cell sorting works well for standard Si solar cells because the bottom and top contacts of standard Si solar cells comprise highly conductive materials such as screen printed Ag. Therefore, when cells are placed on a metallic platform, preferably with vacuum suction so that a good physical contact is established between the metallic platform and the back side of the cell, a low resistance ohmic contact is obtained between the metallic platform and the back side of the cell. The top contact or the busbar is then contacted by temporary, spring loaded contact points, and the front surface of the cell is illuminated. The illuminated current-voltage characteristics are measured between the top temporary contact pins and the metallic platform touching the back side of the device. Since the electrical contact between the back surface of the cell and the metallic platform is good, the measured I-V characteristics do not get influenced by this electrical contact. After cell sorting, devices in each bin are stringed together to form circuits, which, when encapsulated, form the modules. During cell stringing, the back contact on the back surface of a first cell is electrically connected to a front contact or busbar of a second cell by soldering (or by conductive adhesive) a Cu ribbon to the back contact of the first cell and to the busbar of the second cell. There are a variety of automated manufacturing tools available to string the already binned or sorted cells to form cell strings. As can be appreciated the ability to measure the I-V characteristics of a solar cell, i.e. cell sorting or binning, before attaching a Cu-ribbon to the back contact is important for this process flow. Without this capability, high throughput stringing tools cannot be used to form strings and modules.

CIGS thin film solar cells fabricated on metal foil substrates present challenges in terms of cell sorting. When a metal foil based CIGS solar cell is finished by forming the absorber layer, depositing a transparent layer such as a CdS layer, a ZnO layer, a CdS/ZnO stack or a CdS/ZnO/ITO stack over the absorber layer, and forming a finger pattern with busbar(s) on top of the transparent conductive layer, the cell needs to be measured and binned. However, metal foils such as stainless steel foils and aluminum alloy based web that are used for the fabrication of such solar cells, develop poorly conducting surface films on their back surfaces, which are exposed to air and to various process environments employed during the fabrication of the cell. The metal foils also experience high temperatures in the range of 100-600 C during such processes. As a result, when the completed CIGS cell is placed on a metallic platform to measure its I-V characteristics (before attaching a Cu ribbon to its back surface) the electrical contact between the metallic platform and the back surface of the device (which is the back surface of the foil substrate) is poor. Consequently, the measured I-V characteristics, especially the fill factor of the device are negatively impacted by the resistance of this electrical contact. Since the contact resistance between the back surface of the cell and the metallic platform depends on the resistance and thickness of the poorly conducting surface films on the back side of the metallic substrate, the contact resistance changes from cell to cell and is not constant. As a result, binning or sorting of metal foil based CIGS solar cells is not reliable.

Therefore, there is a need to develop approaches that will make cell sorting possible for metal foil based thin film solar cells. There is also a need to improve materials and processing approaches to enhance adhesion at various interfaces in the module structure formed using metal-foil based thin film solar cells. Such improvements are expected to enhance manufacturability and long term reliability of these modules.

### SUMMARY OF THE INVENTION

The present invention generally relates to thin film solar cell fabrication and module packaging, more particularly, to techniques for manufacturing modules based on Group IBIIIAVIA thin film solar cells.

In one aspect there is provided a method of forming a thin film solar cell, the method comprising providing a metallic substrate such that a finished front surface of the metallic substrate has an average roughness of less than 50 nm and a conditioned back surface that has an average roughness of more than 200 nm; and forming a Group IBIIIAVIA compound absorber layer over the finished front surface.

This above aspect may include as the step of providing finishing a front surface of the metallic substrate to obtain the finished front surface so that the average roughness of the finished front surface is less than 50 nm; and roughening a back surface of the metallic substrate to form the conditioned back surface so that the average roughness of the conditioned back surface is more than 200 nm.

In another aspect there is provided a method of manufacturing a solar module, comprising forming a string of solar cells, wherein the string of solar cells include at least two solar cells, and each solar cell includes a light receiving stack with an exposed top surface and a conductive substrate having a rough back surface and a finished front surface over which the light receiving stack is formed, wherein the light receiving stack includes a Group IBIIIAVIA absorber layer, and wherein the average roughness of the rough back surface is more than 500 nm and the average roughness of the finished front surface is less 50 nm; bonding a back packaging layer to the rough back surfaces of the conductive substrates and a front packaging layer to the exposed top surfaces of the light receiving stacks of the solar cells respectively.

In another aspect there is provided a method of attaching a contact lead to the back side of a solar cell structure, comprising laser treating a predetermined area of the back side of the solar cell structure forming a treated back surface area; and attaching the contact lead to the treated back surface area.

In still another aspect there is provided a solar cell, comprising a conductive substrate having a front surface and a back surface including roughness, wherein the average roughness of the back surface is more than 500 nm and the average roughness of the front surface is less than 50 nm; and a Group IBIIIAVIA absorber layer formed over the front surface.

In yet another aspect there is provided a solar cell module, comprising a string of solar cells including at least two solar cells, wherein each solar cell includes a light receiving stack with an exposed top surface and a conductive substrate having a rough back surface and a finished front surface over which the light receiving stack is formed, wherein the light receiving stack includes a Group IBIIIAVIA absorber layer, and wherein the average roughness of the rough back surface is more than 500 nm and the average roughness of the finished front surface is less than 50 nm; a back packaging layer bonded to the rough back surfaces of the conductive substrates; and a front surface packaging layer bonded to the exposed top surfaces of the light receiving stacks.

These and other aspects and advantages of the present invention are described more fully below.

### BRIEF DESCRIPTION OF THE DRAWINGS

FIG. 1 is a side schematic view of a prior-art solar cell;

FIG. 2A is a side schematic cross sectional view of two solar cells taken along the line 2A-2A in FIG. 2B, wherein the solar cells have been interconnected using an embodiment of a process of the present invention;

FIG. 2B is top schematic view of the solar cells shown in FIG. 2A;

FIG. 3 is a schematic view of an embodiment of a system of the present invention;

FIG. 4A is a schematic view of an embodiment of a roll to roll system of the present invention;

FIG. 4B is a schematic top view of a continuous flexible workpiece to process in the roll to roll system shown in FIG. 4A;

FIG. 4C is a schematic cross sectional view of a treating station of the roll to roll system taken along the line 2C-2C in FIG. 4A;

FIG. 5A is a schematic view of an embodiment of a substrate including a roughened back surface;

FIG. 5B is a schematic view of a solar cell structure including the substrate shown in FIG. 5A;

FIG. 6A is schematic view of two interconnected solar cells including the roughened back surface, wherein an encapsulation layer is attached to the roughened back surfaces; and

FIG. 6B is a schematic bottom view of the interconnected solar cells shown in FIG. 6A.

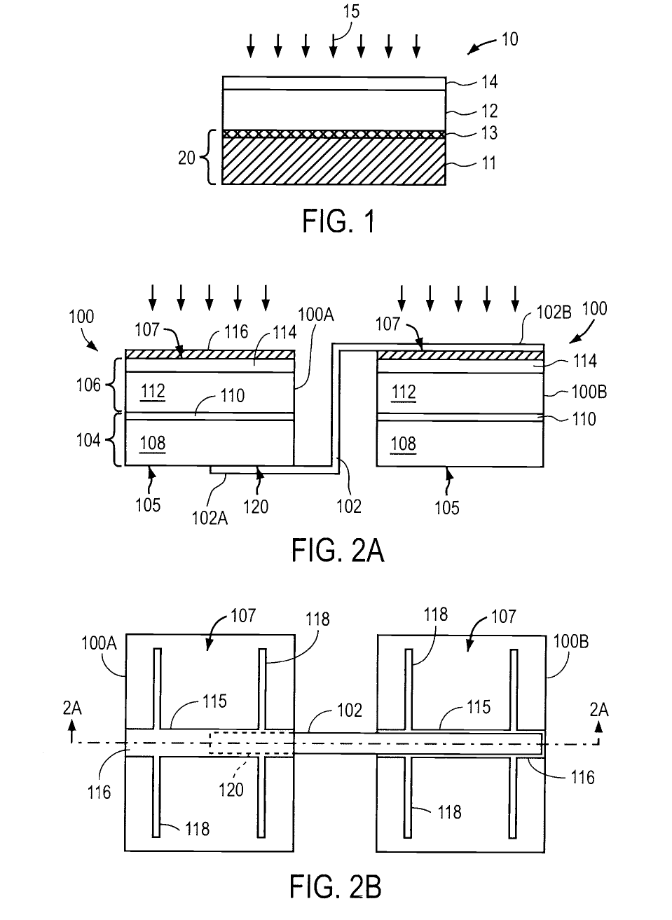

### DETAILED DESCRIPTION OF THE INVENTION

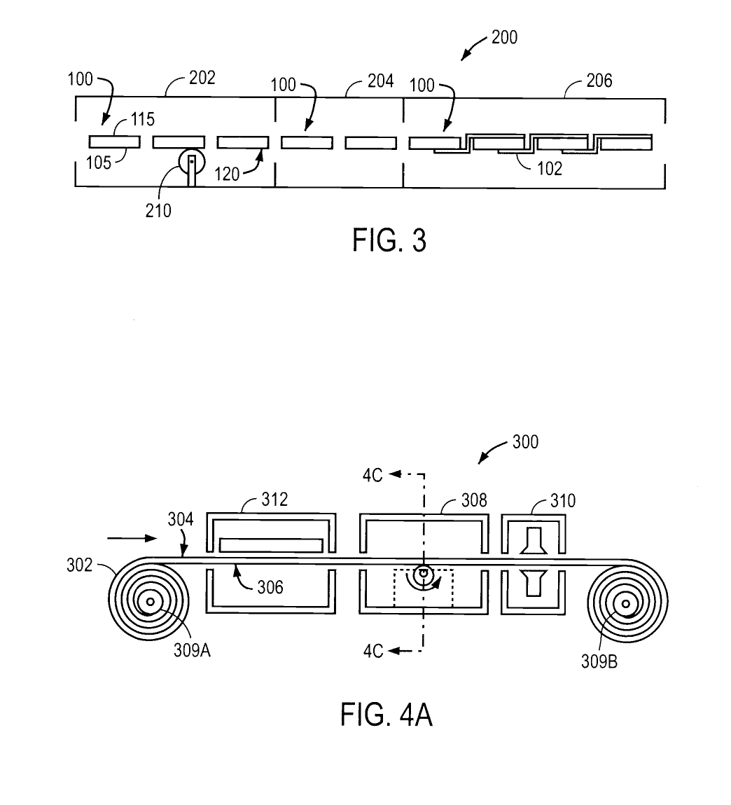

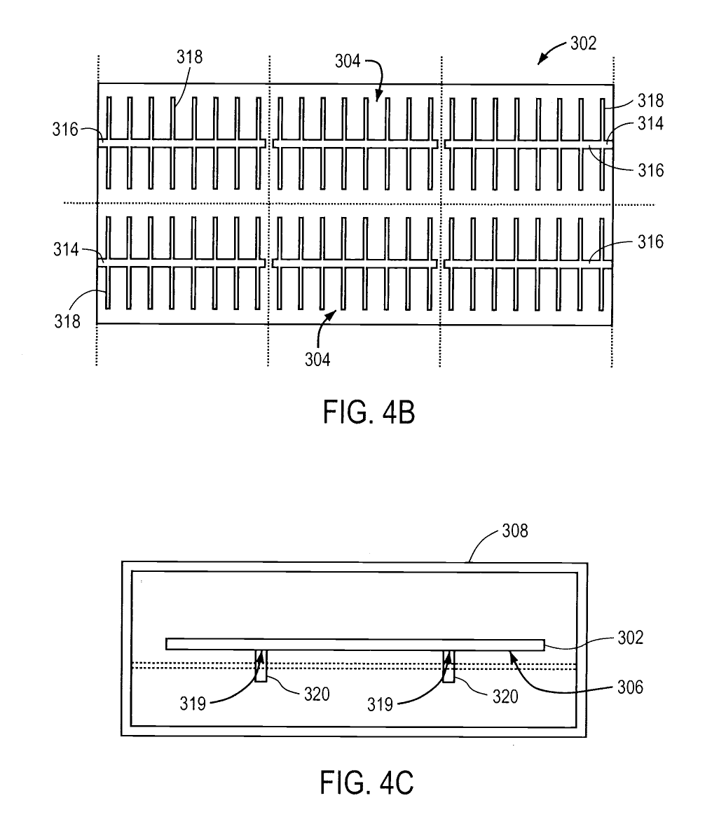

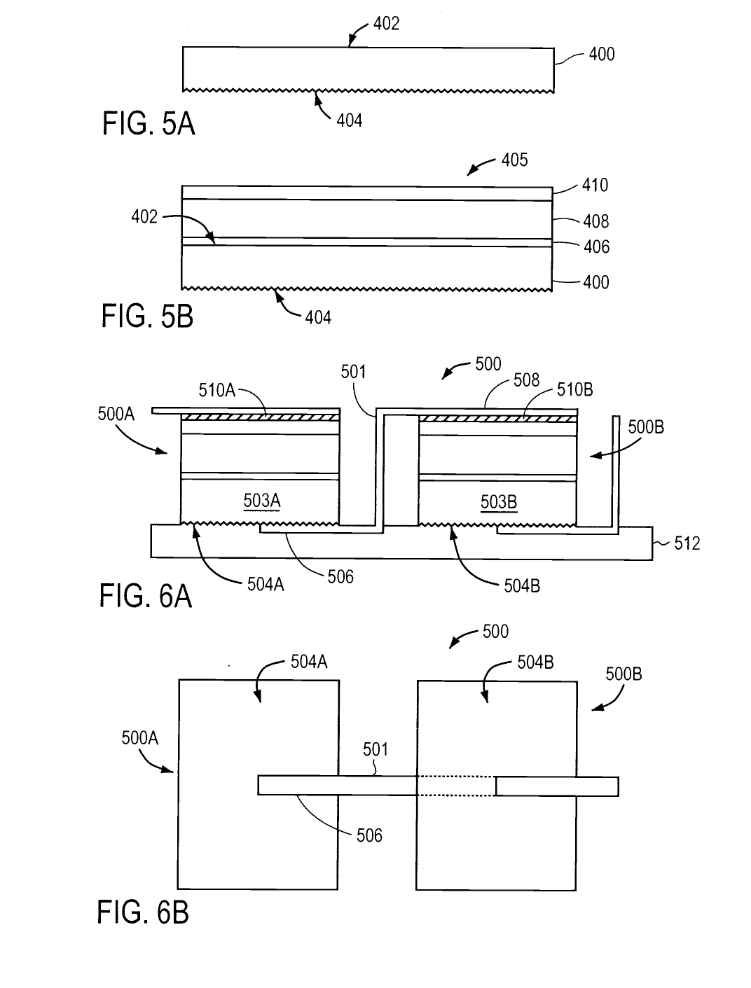

The present invention provides a method and apparatus for treating the back surface of the solar cells having metallic substrates before interconnecting the solar cells for forming circuits and modules. The invention will be described using an interconnection process or stringing process for preferably thin film CIGS solar cells formed on flexible metallic foil substrates. The treatment method is applied to at least a portion of a back surface of the solar cells, i.e., substrate back surface, before establishing electrical contacts to such surfaces. In one embodiment, the treatment process comprises mechanical abrasion and removal of at least a portion of an unwanted non-conductive material film from the substrate surface of the solar cell. As described in the background section, such unwanted material films may be formed on the back surface during selenization, CdS deposition and/or surface oxidation of the metallic substrate surface. In another embodiment, the treatment method applied to the back surface is a roughening process that forms a rough substrate back surface. In the following, FIGS. 2A-3 are used to describe an embodiment of the process of the present invention which employs individual solar cells. FIGS. 4A-4C are used to describe another embodiment using a roll-to-roll process to implement the present invention. Furthermore, FIGS. 5A-6B describe other embodiments employing a flexible metallic substrate having a roughened back surface and a smooth front surface.

FIGS. 2A and 2B show exemplary solar cells 100 such as a first solar cell 100A and a second solar cell 100B which are interconnected by a conductive lead 102, or interconnect, using the process of the present invention. Although the process is exemplified using two solar cells, by using the interconnecting or stringing process of the present invention a plurality of solar cells may be interconnected forming strings and circuits. The conductive lead may be a strip of metal, preferably a conductive ribbon made of copper or any another conductor. Each solar cell 100 comprises a base portion 104 having a back surface 105 and a front portion 106 having a front surface 107. The base portion 104 includes a substrate 108 and a contact layer 110 formed on the substrate. For this embodiment, a preferred substrate material may be a metallic material such as stainless steel, aluminum (Al) or the like. An exemplary contact layer material may be molybdenum (Mo). The front portion 106 may comprise an absorber layer 112, such as a CIGS absorber layer which is formed on the contact layer 110, and a transparent layer 114, such as a buffer-layer/TCO stack, formed on the absorber layer where TCO stands for transparent conductive oxide. An exemplary buffer layer may be a (Cd,Zn)S layer. An exemplary TCO layer may be a ZnO layer, an indium tin oxide (ITO) layer or a stack comprising both ZnO and ITO. A terminal 115, or a finger pattern, including a busbar 116 and conductive fingers 118 may be formed over the front surface 107 as shown in FIG. 2B.

The conductive lead 102 electrically connects a contact area 120 formed on the back side 105 of the solar cell 100A to the terminal 115 of the solar cell 100B. Of course, another contact area may also be formed on the back side of the solar cell 100B to connect the solar cell 100B to the next solar cell (not shown) and so on, in a multiple solar cell stringing scheme. The contact area 120 is formed on the back surface 105 of the solar cell 100A by treating at least a portion of the back surface 105 of the substrate 108. The treatment process is a material removal process which may employ mechanical, chemical, or electrochemical techniques. In the preferred embodiment, the material removal may be performed using friction, such as mechanical brushing or sanding and the like. The treatment process removes at least a portion of the unwanted material layers, such as oxides, selenides or CdS and others, from the back surface 105 and exposes the fresh substrate material itself, thereby forming a contact area substantially free from high resistance species such as oxides, sulfides and selenides. As mentioned above, a chemical, an electrochemical, or electrochemical mechanical material removal technique may also be used to partially or fully clean the unwanted material layers from the back surfaces of the solar cells. For example, the back surfaces of the solar cells 100A and 100B may be electroetched before a stringing process. Electroetching of a metal, unlike electropolishing, leaves a rough surface due to the non-isotropic removal by the etching chemistries. After the electroetching, the back surfaces may be rinsed and dried. Further, a laser ablation method may also be used to partially or fully clean the back surfaces by removing unwanted material layer from the surface before the stringing. Laser processing is preferable because it does not involve mechanically touching the substrate and is easy to apply. Various lasers may be used for this purpose such as diode lasers, eximer laser, CO2 laser, YAG laser, etc. In one embodiment, the method uses ultra-violet (UV) lasers. When the UV beam hits the substrate surface it gets absorbed by the surface layer comprising oxides, selenides, sulfides, etc. Energy transfer from the laser beam to the surface layer ablates and removes the surface layer leaving behind a fresh surface. This freshly exposed substrate portion provides a secure bonding location on the substrate for the conductive lead. In this respect the contact area 120 may be limited to a location on the back surface 105 of the solar cell 100A, which is near the solar cell 100B, as shown in FIGS. 2A and 2B. Alternatively the contact area may be formed as a strip extending across the back surface and aligned with the projection of the busbar. Alternately the contact area may be formed to cover the entire back surface.

During the stringing process, a first end 102A of the conductive lead 102 is attached to the contact location 120. A bonding material may be applied to at least one of the contact area and the surface of the first end 102 before attaching the conductive lead to the contact area. Similarly, a second end 102B of the conductive lead 102 is attached to a location on the busbar 116 of the solar cell 100B using the bonding material. The bonding material may be a conductive adhesive such as Ag-filled adhesive, solder material or the like. Depending on the nature of the bonding material, appropriate process steps, such as application of heat and pressure, are also carried out to bond the ends of the conductive lead to the cells.

FIG. 3 shows an embodiment of a system 200 to implement above described process. The system 200 includes a substrate treating station 202, a cleaning station 204 and a stringing station. A conventional workpiece handling and moving mechanism (not shown) may hold and move solar cells 100 in succession through the stations during the process. The solar cells 100 may include the structural components of the solar cells 100A and 100B shown in FIGS. 2A-2B. However the solar cells are simplified to show the back surface 105 or the substrate surface and the terminal 115 located on top of the solar cells 100. The substrate treating station 202 may include surface abrasion or surface material removal components such as rollers or wheels having abrasive surfaces, sanders, polishers or the like, which may be used to remove material from at least a portion of the back surface 105, thereby electrically activating it. In one embodiment, solar cells 100 entering the substrate treating station may be moved over one or more abrasive roller(s) 210. Alternately, abrasive roller(s) may be moved towards and contacted to the back surface 105. The abrasive roller 210 may continuously or intermittently touch and remove material from the back surface and thereby form the contact areas 120 as described above. The cleaning station 204 may include cleaning components such as vacuum suction systems, brushes, and adhesive rollers to remove particles and dust from the contact area, substrate, terminal and the other parts of the solar cells. It should be noted that it is possible to merge the treating 202 and the cleaning stations 204 in one location, in which case cleaning may be carried out as the surface abrasion is performed. This way, particles forming as a result of the treating process are immediately removed from the surface of the solar cell. In another embodiment the substrate treating station 202 may include a laser in place of or in addition to the surface abrasion component. In this case, a laser beam is directed onto the back surface 105 to ablate and remove material from at least a portion of the back surface 105, therefore leaving a fresh surface that can be electrically contacted in the stringing station 206. The laser beam may be a fixed area beam which may be pulsed. Alternately, a small area laser beam may be scanned over a preselected area of the back surface removing the surface layer from that preselected contact area. The stringing station 206 may include a connector that attaches the conductive leads to the contact areas and the terminals of the solar cells to interconnect them as in the manner described above. The stringing station may also typically contain a dispenser that dispenses the bonding material, such as Ag-filled adhesive, a mechanism to cut and place ribbons over the dispensed adhesive, a mechanism to press the ribbons against the solar cell surface and a heater that heats the strings formed through interconnecting to cure the conductive adhesive. In another embodiment, the treating station 202 may include to electroetch the back surfaces to fully or partially remove high resistivity unwanted layers from the back surface. If the electroetching is used, the cleaning station 204 may have a rinsing/drying apparatus to rinse and dry the back surface before the stringing process.

FIG. 4A shows a roll to roll system 300 to conduct the process of the present invention on a continuous flexible workpiece 302 which is exemplified in FIG. 4B. The continuous workpiece 302 comprises a large scale solar cell structure formed on a large substrate so that it can be later cut into individual solar cells similar to the ones shown in FIGS. 2A-2B before a stringing process. Therefore, a front surface 304 of the continuous workpiece 302 is the surface of a transparent conductive layer, and a back surface 306 is the back surface of a substrate, preferably a metallic substrate such as stainless steel. In the roll to roll processes of the present invention, above described contact areas are formed on the back surface 306 of the continuous workpiece before the cutting of the continuous workpiece.

The system 300 may comprise a treating station 308 and a cleaning station 310. Optionally, a terminal forming station 312 may be added to the system 300 to deposit terminal structures or finger patterns on the solar cell structure before the contact areas are formed on the back surface. During the process, a moving mechanism (not shown) may supply the continuous workpiece 302 from a supply roll 309A and advance through the stations. The processed continuous flexible workpiece is taken up from the cleaning station 206 and wrapped around a receiving roll 309B.

Referring to FIGS. 4A-4B, at a first stage of the roll to roll process, terminal structures 314 are formed on the front surface 304 of the continuous workpiece 302, preferably using a screen printing process. FIG. 4B shows the front surface in top view after forming the terminal structures 314. The terminal structures 314 include busbar lines 316 and conductive fingers 318 that are configured in a fishbone design. Dotted lines depict location of each individual cell which will be cut out from the continuous workpiece after the process of the present invention.

Referring to FIGS. 4A-4C, after forming the terminal structures 314, the continuous workpiece 302 is advanced into the treating station 308 to form contact areas 319 on the back surface 306 of the continuous workpiece 302. The contact areas may be formed by contacting a material remover 320 such as an abrasive roller, to the back surface, and thereby removing at least a part of the non-conductive material film from the substrate of the continuous workpiece. FIG. 4C, shows a cross section of the treating station 308, where material removers 320 form cleaned conductive areas as two strips extending on the back surface. The contact areas 319 are aligned with the busbar lines 316 to enable solar cells to be interconnected as shown in FIGS. 2A-2B. After the treating process the continuous workpiece is advanced into a cleaning station 310 to remove particles and dust formed during the previous process steps and wrapped around the receiving roller 309B. In the following process steps, the workpiece with contact areas may be cut into individual solar cells in a cutting system including a cutter. Individual solar cells with contact areas are then interconnected in a stringing tool. In another embodiment, as described in reference with FIG. 3, the treating station 308 may include a mechanism to electroetch or laser-ablate the back surface 309 to fully or partially remove the high resistivity unwanted material layers from the back surface. If the electroetching is used, the cleaning station 310 may have a rinsing/drying apparatus to rinse and dry the back surface before the stringing process. Thin nature of CIGS solar cells have many benefits including mechanical flexibility, roll-to-roll processing capability, reduced materials cost, etc. However, employing such thin semiconductor layers also presents challenges. For CIGS solar cells fabricated on glass substrates, defect-free thin layers may be grown on the glass surface which is exceptionally flat. However, to grow a defect free 1000-1500 nm thick CIGS absorber layer over a front surface of a substrate, it is desirable to have a front surface roughness of less than about 5% of the absorber layer thickness, preferably less than about 2% of the absorber layer thickness. Otherwise, excessive substrate surface roughness may cause defects in the thin semiconductor absorber, which may introduce electrical shunting paths and negatively impact the solar cell efficiency. Accordingly, it is desirable to have an average substrate front surface roughness (Rₐ) that is less than 50 nm, preferably less than 20 nm. Glass, with a surface roughness of less than 5 nm is ideal for this purpose. The surface roughness of the metallic foil substrates, however, has been historically larger than that of glass (typically in the 50-100 nm range). Therefore, as better rolling methods are developed employing rolls with highly finished surfaces, manufacturers have been reducing the surface roughness of the metal foils provided to thin film solar cell manufacturers. Because such surface quality improvements are achieved by passing the foils between pairs of highly polished rollers under pressure, both the top and bottom surfaces of the foils are improved in terms of surface roughness. However, as will be explained below, smoothening of the back surface of the metal foils in solar cell structures yields undesirable results such as increased contact resistance and reduced reliability of modules manufactured using such solar cells.

In the following embodiments, a treatment process is used to roughen substantially the whole of a back surface of a flexible metallic foil substrate to be used in thin film solar cell manufacturing. In these embodiments, front surface on which the thin film solar cell is deposited or formed is kept smooth with an average roughness value of less than 50 nm. However, the back surface on which the ohmic contact is made is roughened to have an average roughness value of more than 200 nm, preferably 500 nm, most preferably more than 1000 nm. The embodiments will be described using an interconnection process or stringing process for preferably thin film CIGS solar cells formed on flexible metallic foil substrates.

FIG. 5A shows a conductive flexible substrate 400 of the present invention. The conductive flexible substrate 400 is preferably a metallic foil having a front surface 402 and a back surface 404. In this embodiment, different from the above embodiments, the back and optionally the front surfaces of the conductive flexible substrate 400 are surface treated. Surface treatment may be carried out during the manufacture of the conductive flexible substrate, before forming the active layers of the thin film solar cell, or after finishing the solar cell, before applying the ohmic contacts and packaging materials to the back surface. The back surface 404 is treated using a surface treatment process or surface preparation process of the present invention to form a desired surface roughness or profile. With the surface treatment, the back surface may have an average surface roughness of more than about 200 nm, preferably more than 500 nm, and most preferably more than 1000 nm. The back surface with such rough topography provides an increased surface area for bonding of a conductive lead or a packaging material. This improves the adhesion and reduces the contact resistance of the back surface with the conductive lead, and at the same time improving the adhesion between the back surface of the cell and the packaging material employed in module manufacturing. In the context of this application, roughening process refers to forming patterns of peaks and valleys into the back surface 404. Such patterns may be repeating patterns such as the patterns formed by applying an embossment process to the back surface or random patterns by applying an abrasive or by using other surface treatments, such as laser treatments. While the back surface of the flexible foil substrate is roughened, the front surface is maintained as a smooth surface without appreciable profile, and it is essentially a flat surface. A finishing process, such as polishing or planarization may also be applied to the front surface to obtain a desired flatness. Accordingly, the average surface roughness of the front surface 402 is less than 50 nm, preferably less than 20 nm.

The conductive flexible substrate 400 may be surface treated using a number of processes including mechanical abrasion, laser processing, chemical and electrochemical processing, and the like. In one embodiment, the surface treatment may be applied during the processes of forming the conductive flexible substrate, such as the rolling and milling process, which is commonly used to form thin conductive flexible substrates. As is well known, rolling process is one of the processes to manufacture metallic foils, and it involves feeding a metallic sheet into a gap between the cylindrical surfaces of two work rollers disposed parallel to one another. Force applied by the rotating rollers to the back and front surface of the sheet reduces the thickness of the metallic sheet as it travels through the gap between the work rollers. Accordingly, the back surface may be roughened using a work roller having a pattern on its cylindrical surface. As the conductive flexible substrate is rolled between the work rollers, a repeating pattern of a predetermined profile, i.e., peaks and valleys, may be embossed on the back surface of the conductive flexible substrate by the work roller pressing against the back surface 404. While the back surface is patterned, the front surface 402 may be made flat by applying a work roller with a smooth finished surface which has no pattern against the front surface.

In another embodiment of the surface treatment process, the back surface of the conductive flexible substrate is roughened by applying abrasives to the back surface 404. This process removes at least a portion of the surface material from the back surface to form the roughness. This approach may involve using material removing power tools such as rotary sanders, which roughen the back surface by forming repeating or random profiles on the back surface.

As described before, laser treatment or ablation may be used to clean the back surface of metal foil based thin film CIGS solar cells irrespective of the roughness of the back surface. Such a process enables the cell measurement or sorting step in an automated manufacturing line. Additionally, laser treatment such as laser ablation may also be used to roughen the back surface of the conductive flexible substrate by applying higher power laser beams. In a laser ablation process, a portion of the surface material is removed by irradiating the back surface with a laser beam, preferably with a pulsed laser beam. Laser treatment may be performed in a controlled fashion to form repeated patterns or random profile patterns on the back surface while at the same time cleaning the back surface.

Further, the roughness may be formed by chemical or electrochemical etching which etches peaks and valleys into the back surface 404. After or before any of the above surface treatments applied to the back surface, the front surface may additionally be electropolished to form a substantially smooth finish. Alternatively, laser finishing or polishing may also be used to reduce surface roughness of the front surface 402. After the surface treatment processes, especially the ones involving etchants, front and the back surfaces of the conductive flexible substrate may be cleaned and/or rinsed to remove chemical residues and/or solid particles.

After the surface treatment of the back surface 404 and optionally the front surface 402, a solar cell stack 405 is formed as shown in FIG. 5B. The solar cell stack 405 includes a contact layer 406 formed on the front surface 402 of the conductive flexible substrate 400, an absorber layer 408 on the contact layer 406, and a transparent layer 410 such as a buffer layer/TCO stack on the absorber layer 408. If any oxidation or contamination of the back surface 404 occurs during the formation of the solar cell stack 405, a second surface treatment may be performed to remove the contamination mechanically or chemically or by laser as described before. This surface cleaning does not affect the roughness of the back surface. It only removes a contamination or surface layer. However in any event, whether a second surface treatment process is performed or not, the electrical resistance of a contact attached to the rough back surface of the special substrate of the present invention will be lower than the resistance of a contact attached to a smooth back surface because the contact area for a roughened surface is lower. Furthermore, the adhesion of the contact lead to the rough back surface is enhanced.

The absorber layer thickness for the thin film solar cell of the present invention is in the range of 700-2000 nm, preferably in the range of 1000-1500 nm. The absorber layer 408, which may comprise a CIGS or CIGS(S) semiconducting compound, is formed on the contact layer 406 which is deposited on the front surface 402 of the conductive flexible substrate or the metallic foil, which may have a thickness of about 25000-75000 nm. The buffer layer of the transparent layer 410 may comprise a sulfide material such as cadmium sulfide and/or indium sulfide. The TCO may comprise transparent conductive oxides such as indium tin oxide, zinc oxide and indium zinc oxide, etc. The typical thicknesses of the contact layer 406, the buffer layer and the TCO are in the range of 200-600 nm, 30-100 nm and 100-500 nm, respectively. Therefore the total thickness of the active layers of the solar cell (excluding the conductive flexible substrate thickness) is in the range of 1000-3000 nm. This thickness is much lower than that of a typical crystalline Si solar cell which has a thickness of about 100000-150000 nm.

As described before, smooth metallic substrate back surface is undesirable in terms of contact resistance and reliability especially when several solar cells are interconnected to form circuits and then packaged to form modules. FIGS. 6A and 6B show an exemplary solar cell module section 500 including a first solar cell 500A and a second solar cell 500B interconnected by a conductive lead 501 such as a Cu-based ribbon. The solar cells 500A and 500B may be cut out of the solar cell structure 405 and include substrates 503A and 503B. As described above, one of the ohmic contacts to the first solar cell 500A is made on a back surface of the substrate 503A by attaching a conductive lead to the back surface using a conductive adhesive. As shown in FIG. 6A, a first end 506 of the conductive lead 501 is attached to the back surface 504A of the substrate 503A of the first solar cell 500A, and the second end 508 of the conductive lead 501 is attached to a terminal 510B or a busbar of the second solar cell 500B. As opposed to a smooth back surface of the prior art, the rough back surface 404 of the substrate 503A and the substrate 503B provides an increased surface area for the bonding of the conductive lead 501 and thus reduces contact resistance compared to a smooth back surface. Adhesion of the contact to the back surface is also enhanced with roughness of the back surface.

Referring back to FIG. 6A, an exemplary packaging material layer 512 such as Ethyl Vinyl Acetate (EVA) or thermo-plastic sheet may also be attached to the back surfaces 504A and 504B as well as to the top surface of the cells (top EVA or thermo-plastic layer is not shown in the figure for brevity). In a typical packaging process, a group of stringed solar cells are sandwiched between the packaging material layers. The top and bottom packaging layers may be made of multiple layers. As shown in FIG. 6B in a bottom view, the conductive leads 501 may be attached to a portion of the back surfaces so that the remaining portions of the back surfaces 504A and 504B are available to attach the packaging layers. The adhesion of the packaging materials such as EVA and thermo-plastics to a rough back surface is enhanced compared to the adhesion to a smooth back surface of the prior art. Low adhesion at the packaging/substrate interface negatively impacts the long term reliability of the module because the module package has to pass rigorous accelerated testing including temperature cycling between −40° C. and +85° C., humidity freeze testing, humidity temperature testing, etc. Weakly adhering interfaces are areas that fail and separate during such testing. Accordingly, present invention uses a unique metal foil structure that provides a smooth front surface for the construction of a defect free active region of a thin film solar cell and at the same time provide a rough back surface so that reliable electrical contacts may be fabricated on that surface and a robust module may be processed using these cells. Heat and pressure may be applied to the packaging layers to adhere them to the rough back surface and the light receiving top portion of the solar cell.

Although the present invention is described with respect to certain preferred embodiments, modifications thereto will be apparent to those skilled in the art.

We claim:

1. A method of forming a thin film solar cell, the method comprising:
providing a metallic substrate such that a finished front surface of the metallic substrate has an average roughness of less than 50 nm and a conditioned back surface that has an average roughness of more than 200 nm; and
forming a solar cell absorber layer over the finished front surface.

2. The method according to claim 1 wherein the step of providing includes the steps of:
finishing a front surface of the metallic substrate to obtain the finished front surface so that the average roughness of the finished front surface is less than 50 nm; and
roughening a back surface of the metallic substrate to form the conditioned back surface so that the average roughness of the conditioned back surface is more than 200 nm.

3. The method of claim 2 further comprising forming a contact layer on the finished front surface and depositing a transparent layer on the solar cell absorber layer wherein the solar cell absorber layer is a Group IBIIIAVIA compound absorber layer and wherein the Group IBIIIAVIA compound absorber layer is formed on the contact layer.

4. The method of claim 3 wherein the step of roughening results in a conditioned back surface with an average surface roughness of at least 500 nm.

5. The method of claim 4 wherein the step of roughening results in a conditioned back surface with an average surface roughness of at least 1000 nm.

6. The method of claim 3 further comprising attaching a conductive lead to the conditioned back surface.

7. The method of claim 6 wherein the step of attaching attaches the conductive lead to the conditioned back surface using a conductive adhesive.

8. The method of claim 7, wherein the step of roughening comprises embossing peaks and valleys to the back surface.

9. The method of claim 8, wherein the step of finishing the front surface to obtain the finished front surface comprises applying force to the front surface by a surface of a polished roll, and embossing peaks and valleys to the back surface comprises applying force to the back surface by a surface of a roll comprising peaks and valleys.

10. The method of claim 7, wherein the step of roughening comprises one of abrading the back surface, laser treating the back surface, chemically etching the back surface and electrochemically etching the back surface.

11. The method of claim 3, wherein the step of finishing the front surface to obtain the finished front surface comprises one of applying force to the front surface by a surface of a polished roll, electropolishing, chemical polishing, chemical mechanical polishing and laser finishing.

12. The method of claim 7 further comprising a step of cleaning the conditioned back surface before the step of attaching.

13. The method of claim 12, wherein the step of cleaning comprises at least one of abrading and laser ablation of the areas of the conditioned back surface where the step of attaching is applied.

14. The method according to claim 11 further comprising:
attaching at least one electrical lead onto the conditioned back surface.

15. The method of claim 14 wherein the metallic substrate is one of stainless steel foil and aluminum alloy foil.

16. The method of claim 14 wherein the step of roughening the back surface comprises at least one of abrading the back surface and laser treating the back surface.

17. The method of claim 16 wherein the step of attaching attaches the at least one electrical lead onto the conditioned back surface using a conductive adhesive material.

18. The method of claim 1 wherein the metallic substrate is one of stainless steel foil and aluminum alloy foil.

19. A method of manufacturing a solar module, comprising:
forming a string of solar cells, wherein the string of solar cells include at least two solar cells, and each solar cell includes a light receiving stack with an exposed top surface and a conductive substrate having a rough back surface and a finished front surface over which the light receiving stack is formed, wherein the light receiving stack includes a Group IBIIIAVIA absorber layer, and wherein the average roughness of the rough back surface is more than 500 nm and the average roughness of the finished front surface is less 50 nm;
bonding a back packaging layer to the rough back surfaces of the conductive substrates and a front packaging layer to the exposed top surfaces of the light receiving stacks of the solar cells respectively.

20. The method of claim 19 wherein the step of bonding comprises interposing the string of solar cells between the back packaging layer and the front packaging layer and subjecting the back and the front packaging layers and the string of solar cells to heat and pressure.

21. The method of claim 20, wherein the front and back packaging materials comprise ethylene vinyl acetate copolymer.

22. The method of claim 20, wherein the front and back packaging materials comprise thermo plastic material.

23. The method of claim 22, wherein the thermo plastic material comprises thermoplastic polyurethane.

24. A method of attaching a contact lead to the back side of a solar cell structure, comprising
laser treating a predetermined area of the back side of the solar cell structure forming a treated back surface area; and
attaching the contact lead to the treated back surface area.

25. The method of claim 24 wherein the step of laser treating utilizes a laser beam that ablates a surface layer of the predetermined area.

26. The method of claim 25 wherein the step of laser treating employs an UV laser.

27. The method of claim 25 further comprising a step of roughening the back side of the solar cell structure before the step of laser treating so that roughening yields an average surface roughness of more than 500 nm.

28. The method of claim 27 wherein the step of roughening is carried out using mechanical abrasion.

29. A solar cell, comprising:
a conductive substrate having a front surface and a back surface including roughness, wherein the average roughness of the back surface is more than 500 nm and the average roughness of the front surface is less than 50 nm; and
a Group IBIIIAVIA absorber layer formed over the front surface.

30. The solar cell of claim 29, wherein the conductive substrate comprises at least one of stainless steel and aluminum.

31. The solar cell of claim 29 further comprising a transparent layer formed on the Group IBIIIAVIA absorber layer.

32. The solar cell of claim 31 further comprising a contact layer interposed between the front surface of the conductive substrate and the Group IBIIIAVIA absorber layer.

33. The solar cell of claim 32, wherein the roughness is a repeating profile formed on the back surface.

34. The solar cell of claim 32, wherein the roughness is a repeating embossment formed on the back surface.

35. The solar cell of claim 32, wherein the roughness includes randomly distributed peaks and valleys.

36. The solar cell of claim 32 further comprising a conductive lead attached to the back surface.

37. The solar cell of claim 36 further comprising a conductive adhesive between the conductive lead and the back surface.

38. A solar cell module, comprising:
a string of solar cells including at least two solar cells, wherein each solar cell includes a light receiving stack with an exposed top surface and a conductive substrate having a rough back surface and a finished front surface over which the light receiving stack is formed, wherein the light receiving stack includes a Group IBIIIAVIA absorber layer, and wherein the average roughness of the rough back surface is more than 500 nm and the average roughness of the finished front surface is less than 50 nm;
a back packaging layer bonded to the rough back surfaces of the conductive substrates; and
a front surface packaging layer bonded to the exposed top surfaces of the light receiving stacks.

39. The module of claim 38, wherein the front and back packaging materials comprise ethylene vinyl acetate copolymer.

40. The module of claim 38, wherein the front and back packaging materials comprise thermo plastic material.

41. The module of claim 40, wherein the thermo plastic material comprises thermoplastic polyurethane.
